(19) United States
(12) Patent Application Publication
(10) Pub. No.: US 2019/0267766 A1
(43) Pub. Date: Aug. 29, 2019

(54) Measuring Device for Measuring the Wear of Carbon Brushes

(71) Applicant: Bayerische Motoren Werke Aktiengesellschaft, Muenchen (DE)

(72) Inventor: Silko FEUSTEL, Muenchen (DE)

(21) Appl. No.: 16/407,688

(22) Filed: May 9, 2019

Related U.S. Application Data
(63) Continuation of application No. PCT/EP2017/077095, filed on Oct. 24, 2017.

(30) Foreign Application Priority Data
Nov. 23, 2016 (DE) 10 2016 223 155.3

(51) Int. Cl. H01R 39/58; H01R 39/20; G01R 31/34

(52) U.S. Cl. CPC H01R 39/58; H01R 2201/26; G01R 31/343; H01R 39/20

(57) ABSTRACT

A measuring device for measuring the wear of carbon brushes includes: a slip ring; a carbon brush, which is arranged for sliding in a sliding direction and which is preloaded into sliding contact with the slip ring; and an indicator material, which extends in the sliding direction in, on or next to the carbon brush and is connected to the carbon brush in such a way that the indicator material moves together with the carbon brush at least with respect to the sliding direction. The indicator material is preloaded into sliding contact with the slip ring. An insulator is arranged between the carbon brush and the indicator material and electrically insulates the carbon brush from the indicator material. A resistance-measuring apparatus measures the resistance between two measurement points, between which at least a section of the indicator material and a section of the slip ring lie, wherein the specific resistance of the indicator material is greater than the specific resistance of the carbon brush.

### CROSS REFERENCE TO RELATED APPLICATIONS

This application is a continuation of PCT International Application No. PCT/EP2017/077095, filed Oct. 24, 2017, which claims priority under 35 U.S.C. § 119 from German Patent Application No. 10 2016 223 155.3, filed Nov. 23, 2016, the entire disclosures of which are herein expressly incorporated by reference.

### BACKGROUND AND SUMMARY OF THE INVENTION

The invention relates to a device for measuring the wear of carbon brushes, to an electric machine having such a device for measuring the wear of carbon brushes and also to a vehicle having such an electric machine.

Devices that render it possible to ascertain a wear limit of carbon brushes of electric motors are known from the prior art. If in this case the carbon brush reaches a wear limit, this wear limit is then detected, for example, in an electrical or optical manner and may be accordingly displayed. Such devices are disclosed by way of example in DE 197 55 232 A1 and U.S. Pat. No. 4,761,594 A. However, in the case of such devices, wear of the carbon brushes is only determined by means of two states, such as, for example, “carbon brush sufficiently long” and “carbon brush no longer sufficiently long”. A continuous procedure for determining the actual carbon brush length, by way of example in a % of the original length, is not possible using such devices.

Within the context of the increasing prevalence of electromobility and the increased requirement that is therefore made for reliability of electric machines (electric motors and/or generators), in particular for driving motor vehicles, there is however the desire for a more precise procedure for determining the abrasion of carbon brushes.

One object of the invention resides in determining more precisely the wear of carbon brushes of an electric machine. This object is achieved by a device for measuring the wear of carbon brushes, an electric machine, and a vehicle, according to embodiments of the invention.

In accordance with one exemplary embodiment of the invention, a device for measuring the wear of carbon brushes is provided, having a slip ring; a carbon brush that is arranged in a displaceable manner along a direction of displacement and is pre-stressed in sliding contact with the slip ring; an indicator material that extends in, on or adjacent to the carbon brush along the direction of displacement and is connected to the carbon brush such that said indicator material moves together with the carbon brush at least in relation to the direction of displacement, wherein the indicator material is pre-stressed in sliding contact with the slip ring; an insulator that is arranged between the carbon brush and the indicator material and that electrically insulates the carbon brush from the indicator material; and a resistance measuring device for measuring a resistance between two measuring points, at least one section of the indicator material and a section of the slip ring being between said two measuring points, wherein a specific electrical resistance of the indicator material is greater than a specific electrical resistance of the carbon brush.

In accordance with a further exemplary embodiment of the invention, a device for measuring the wear of carbon brushes is provided, furthermore having a device for determining the wear of carbon brushes, which determines by way of the measured resistance a length of the carbon brush along the direction of displacement.

In accordance with a further exemplary embodiment of the invention, a specific resistance of the indicator material is at least one hundred times greater than a specific resistance of the carbon brush. In particular, a specific resistance of the indicator material is at least one thousand times greater than a specific resistance of the carbon brush. In particular, a specific resistance of the indicator material is at least ten thousand times greater than a specific resistance of the carbon brush.

In accordance with a further exemplary embodiment of the invention, in addition at least one section of the carbon brush is between the two measuring points. In particular, the section of the indicator material has a higher resistance than the one section of the carbon brush. In particular, the section of the indicator material has a resistance that is one hundred times greater than the section of the carbon brush, more preferably a resistance that is a thousand times greater and yet, more preferably, a resistance that is ten thousand times greater.

In accordance with a further exemplary embodiment of the invention, one of the measuring points is arranged on the end of the indicator material that is remote from the slip ring and the other measuring point is arranged on the end of the carbon brush that is remote from the slip ring or on an electrical conductor to the carbon brush.

Furthermore, the invention provides an electric machine having at least one device for measuring the wear of carbon brushes in accordance with any one of the preceding exemplary embodiments, and a motor vehicle having such an electric machine.

Other objects, advantages and novel features of the present invention will become apparent from the following detailed description of one or more preferred embodiments when considered in conjunction with the accompanying drawings.

### BRIEF DESCRIPTION OF THE DRAWINGS

FIG. 1 illustrates a device for measuring the wear of carbon brushes in accordance with a first exemplary embodiment of the invention.

FIG. 2 illustrates a device for measuring the wear of carbon brushes in accordance with a second exemplary embodiment of the invention.

### DETAILED DESCRIPTION OF THE DRAWINGS

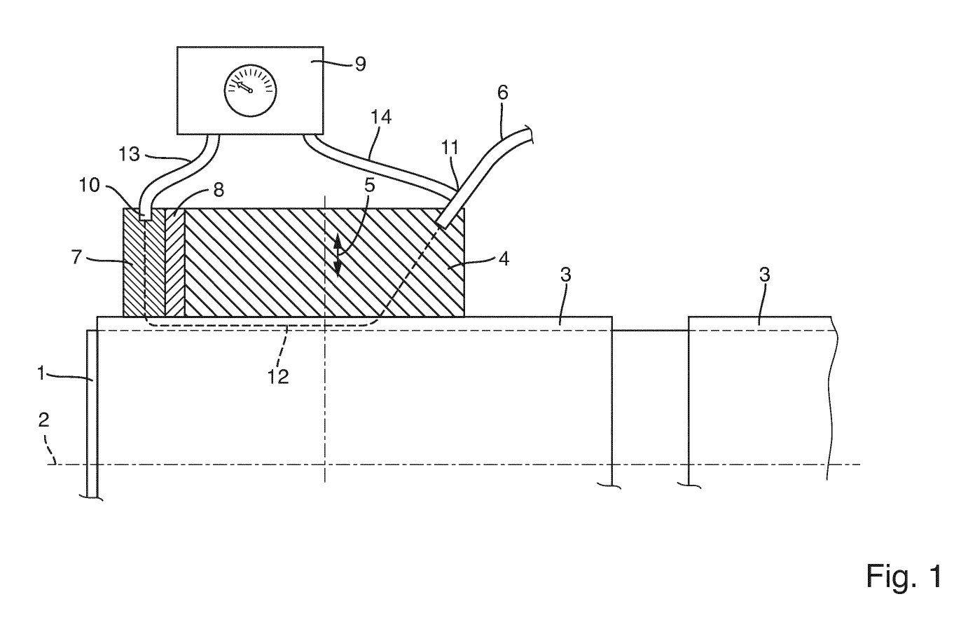

FIG. 1 illustrates a device for measuring the wear of carbon brushes in accordance with a first exemplary embodiment of the invention. The device for measuring the wear of carbon brushes is preferably used in an electric machine (electric motor and/or generator) that comprises in a known manner a rotor having rotor windings, said rotor being mounted on a shaft 1. The rotor is rotatably mounted about an axis of rotation 2 and cooperates electromagnetically with a stator. The rotor windings are electrically connected to slip rings 3 (by way of example two) and may consequently be electrically connected via the slip rings 3 to the non-rotating construction of the electric machine, in particular may be supplied with electrical energy. The slip rings 3 are electrically conductive annular rings that are closed or combined from circular segments, in particular embodied from metal, preferably copper.

Each slip ring 3 is allocated at least one carbon brush 4, preferably multiple, by way of example three carbon brushes 4, that cooperate with the slip ring 3. The carbon brush 4 may be displaceably arranged in a direction of displacement 5 and is pre-stressed toward the slip ring 3. The result is that an electrical contacting arrangement is produced between the carbon brush 4 and the slip ring 3. Since the slip ring 3 may rotate with respect to the carbon brush 4, a sliding contact or slide contact is produced between the carbon brush 4 and the slip ring 3. The direction of displacement 5 is a direction toward the slip ring 3 and away from the slip ring 3, preferably a direction perpendicular with respect to the axis of rotation 2. The pre-stressing arrangement of the carbon brush 4 is realized by way of example by means of a spring.

The carbon brush 4 is electrically conductive and preferably a block-shaped solid material. It is preferred that the carbon brush 4 is embodied from graphite but other materials, in particular metals, for example copper, are possible. The block-shaped solid material is preferably essentially cuboid. The carbon brush 4 is connected to an electrical conductor 6 so as to supply the rotor with energy. It is preferred that the conductor 6 is electrically connected to the material of the carbon brush 4 on the side of the carbon brush 4 that is remote from the slip ring 3. In the case of multiple carbon brushes 4, these carbon brushes are arranged distributed in the circumferential direction of the slip ring 3 with the result that a current that is passed through the carbon brush 4 to the slip ring 3 may be distributed to multiple carbon brushes 4.

In the first exemplary embodiment, an indicator material 7 is arranged adjacent to the carbon brush 4, wherein an insulating material 8 is provided between the carbon brush 4 and the indicator material 7 in order to electrically insulate the carbon brush 4 from the indicator material 7. The indicator material 7 extends along the direction of displacement 5. The indicator material 7 preferably extends continuously over the entire length of the carbon brush 4 along the direction of displacement 5. In FIG. 1, the indicator material 7 is arranged on or adjacent to the carbon brush 4. The indicator material 7 may however also be arranged within the carbon brush 4, by way of example in an elongated hole. The indicator material 7 preferably has the same dimensions in the direction of displacement 5 as the carbon brush 4. The indicator material 7 is essentially more resistant than the material of the carbon brush 4, in other words the indicator material has a higher specific electrical resistance. The insulating material 8 may be, by way of example, a synthetic material. In this case, it is essential that the indicator material 7 is fastened directly or indirectly to the carbon brush 4 in such a manner that the indicator material 7 moves together with the carbon brush 4 in relation to the direction of displacement 5. The indicator material is embodied from a material or a material composite comprising materials and a construction, as is known from the construction of electrical resistors (in the sense of electronic components). In this case, the resistance of the indicator material 7 is to be taken into account as a characteristic for the design. By way of example, the specific resistance of the indicator material 7 is at least one hundred times, in particular at least one thousand times, and preferably at least ten thousand times greater than a specific resistance of the carbon brush 4. Another characteristic that is to be taken into account is the abrasion behavior, wherein an abrasion of the indicator material 7 is to be identical or greater than that of the carbon brush 4 in order to prevent the carbon brush 4 from abrading more rapidly or more easily than the indicator material 7, which may otherwise lead to a deterioration of the electrical contact arrangement between the carbon brush 4 and the slip ring 3.

A resistance measuring device 9 measures a resistance between two measuring points 10 and 11. In the illustrated case, one of the measuring points 10 on the side that is remote from the slip ring is connected to the indicator material 7 and the other measuring point 11 is connected to the carbon brush-side end of the conductor 6. The measuring point 11 may however likewise be arranged on the side of the carbon brush 4 that is remote from the slip ring or on any point of the conductor 6. The current path of the measuring current that is applied by the resistance measuring device, the resistance of said current path being measured by the resistance measuring device 9, is indicated in FIG. 1 with the dashed line 12. Consequently, in the first exemplary embodiment between the two measuring points there is at least:

(i) a section of the indicator material 7, more precisely the section between on the one hand the measuring point 10 and on the other hand the contact site between the indicator material 7 and the slip ring 3,
(ii) a section of the slip ring 3, more precisely the section between on the one hand the contact site between the indicator material 7 and the slip ring 3 and on the other hand the contact site between the slip ring 3 and the carbon brush 4, and
(iii) a section of the carbon brush 4, more precisely the section between on the one hand the contact site between the slip ring 3 and the carbon brush 4 and on the other hand the connection point of the conductor 6 (if the measuring point 11 is on the conductor 6) or the measuring point 11 (if the measuring point 11 is on the carbon brush 4).

The resistance measuring device 9 is electrically connected using conductors 13 and 14 to the measuring points 10 and 11. The resistance measuring device 9 includes a constant current source for the resistance measurement, said current source influencing the conductors 13 and 14 and also the current path that is between the measuring points 10 and 11 with a constant current. The resistance measurement and the procedure of introducing the constant current that is associated with said resistance measurement may be implemented both during operation of the electric machine as well as when said electric machine is at a standstill. For a transfer of energy that is as loss-free as possible, it is desirable that the slip rings 3 and also the carbon brush 4 comprise as low an electrical resistance as possible. However, the indicator material 7 is embodied from a material that, in comparison to this, is highly resistant. The result is that within the current path 12 nearly the entire voltage drops at the section of the indicator material 7. In other words, the measured resistance essentially corresponds to the resistance of the section of the indicator material 7 since the remaining sections may be ignored owing to the much lower specific resistance. Since the indicator material 7 comprises a high specific resistance, the resistance between the measuring points 10 and 11 is dependent upon the length of the indicator material 7. In other words, it is possible via the measured resistance value between the measuring points 10 and 11, which corresponds essentially to the resistance value at the section of the indicator material 7, to determine the remaining length of the indicator material 7 and, consequently, in turn to determine the length of the remaining carbon brush 4.

Should a carbon brush 4 and the indicator material 7 that is associated therewith lose contact with the slip ring 3 in the case of multiple carbon brushes 4 per slip ring (and the indicator material 7 that is respectively associated therewith), a current circuit interruption and consequently a loss of contacting arrangement may then be detected by the resistance measuring device 9 and, by way of example, a user may be notified of a need for maintenance.

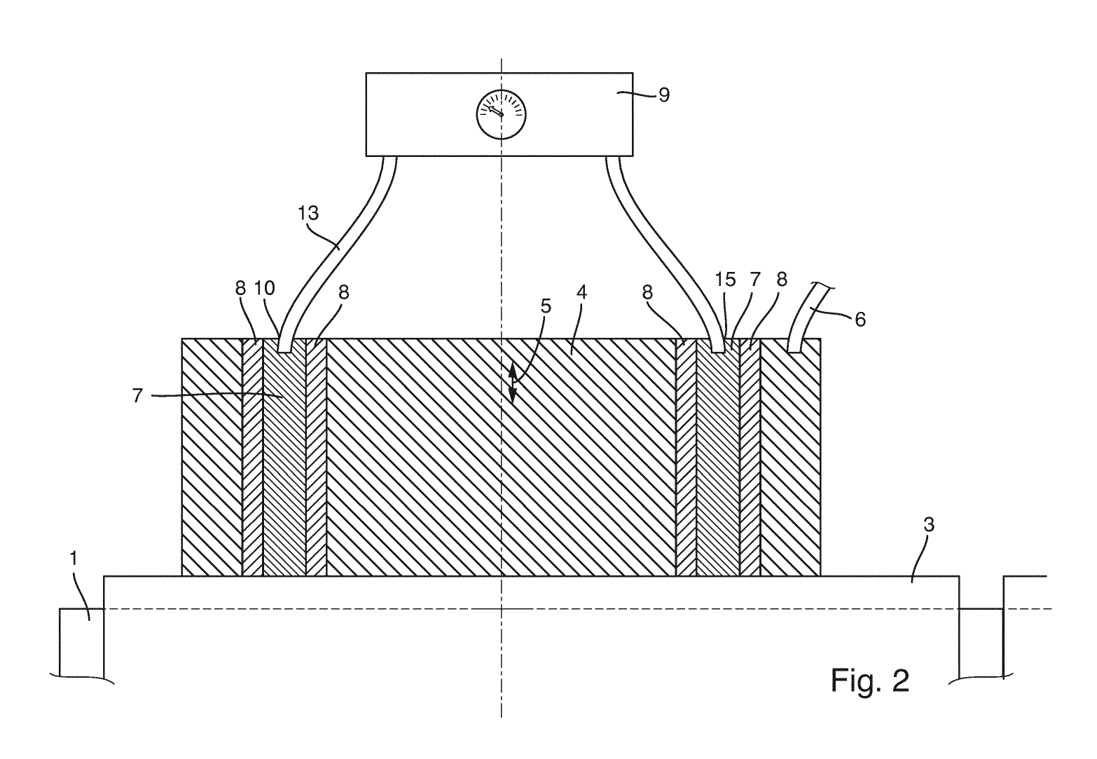

FIG. 2 illustrates a device for measuring the wear of carbon brushes in accordance with a second exemplary embodiment of the invention. In order to avoid repetition reference is made to the description of the first exemplary embodiment in relation to the second exemplary embodiment and only differences with respect to the first exemplary embodiment are explained. As is illustrated in FIG. 2, the indicator material 7 is arranged within the carbon brush 4, by way of example by means of through-holes, however said indicator material may also be arranged on the side of or adjacent to the carbon brush 4. In lieu of a single indicator material 7, a first and a second indicator material 7 are provided in the second exemplary embodiment. Of the two measuring points, at which the resistance measuring device 9 measures the resistance, in the second exemplary embodiment one of the measuring points 10 is arranged on the first indicator material 7, as described in the first exemplary embodiment in relation to the single indicator material. The second measuring point 15 is arranged on the second indicator material 7, as described in the first exemplary embodiment in relation to the single indicator material. A section of the first indicator material 7, a section of the slip ring 3 and a section of the second indicator material 7 is consequently between the two measuring points 10 and 15 in the second exemplary embodiment. Since the indicator material is highly resistant, the measured voltage essentially drops at the two sections of the first and second indicator material. In other words, the measured resistance value between the measuring points 10 and 15 corresponds essentially to the resistance value of the two sections of the first and second indicator material since the resistance value of the remaining sections may be ignored. The result is that it is possible via the measured resistance to determine a length of the indicator material and consequently to determine a length of the carbon brush 4.

The foregoing disclosure has been set forth merely to illustrate the invention and is not intended to be limiting. Since modifications of the disclosed embodiments incorporating the spirit and substance of the invention may occur to persons skilled in the art, the invention should be construed to include everything within the scope of the appended claims and equivalents thereof.

What is claimed is:

1. A device for measuring wear, comprising:
a slip ring;
a carbon brush that is arranged in a displaceable manner along a direction of displacement and is pre-stressed in sliding contact with the slip ring;
an indicator material that extends in, on or adjacent to the carbon brush along the direction of displacement and is connected to the carbon brush such that said indicator material moves together with the carbon brush at least in relation to the direction of displacement, wherein the indicator material is pre-stressed in sliding contact with the slip ring;
an insulator that is arranged between the carbon brush and the indicator material and that electrically insulates the carbon brush from the indicator material; and
a resistance measuring device that measures a resistance between two measuring points, at least one section of the indicator material and a section of the slip ring being between said two measuring points, wherein a specific resistance of the indicator material is greater than a specific resistance of the carbon brush.

2. The device for measuring wear according to claim 1, wherein
a length of the carbon brush along the direction of displacement is determined by the measured resistance.

3. The device for measuring wear according to claim 1, wherein
the specific resistance of the indicator material is at least one hundred times greater than the specific resistance of the carbon brush.

4. The device for measuring wear according to claim 1, wherein
at least one section of the carbon brush is additionally between the two measuring points.

5. The device for measuring wear according to claim 4, wherein
one of the measuring points is arranged on an end of the indicator material that is remote from the slip ring, and
the other measuring point is arranged on an end of the carbon brush that is remote from the slip ring or on an electrical conductor to the carbon brush.

6. An electric machine comprising at least one device for measuring wear according to claim 1.

7. A motor vehicle comprising an electric machine according to claim 6.

8. The device for measuring wear according to claim 1, wherein
the indicator material extends through the carbon brush.

9. The device for measuring wear according to claim 1, further comprising:
a plurality of carbon brushes arranged in a displaceable manner along a direction of displacement and being pre-stressed in sliding contact with the slip ring; and
an indicator material that extends in, on or adjacent to, the plurality of carbon brushes.
